(19) United States
(12) Patent Application Publication
(10) Pub. No.: US 2015/0075707 A1
(43) Pub. Date: Mar. 19, 2015

(54) METHOD FOR MANUFACTURING A SEMI-FINISHED PRODUCT FOR A MODULE HAVING A CELL MADE FROM A PHOTOACTIVE MATERIAL, SEMI-FINISHED PRODUCT AND DEVICE FOR THE MANUFACTURE THEREOF

(71) Applicants: Dirk Albrecht, Fehrbellin (DE); Nico Schramm, Neuruppin (DE); Heinz Buschmann, Neuruppin (DE)

(72) Inventors: Dirk Albrecht, Fehrbellin (DE); Nico Schramm, Neuruppin (DE); Heinz Buschmann, Neuruppin (DE)

(73) Assignee: SITEC Solar GmbH, Neuruppin (DE)

(21) Appl. No.: 14/364,197

(22) PCT Filed: Aug. 20, 2012
(86) PCT No.: PCT/DE2012/100243

§ 371 Date: Nov. 10, 2014

(30) Foreign Application Priority Data
Dec. 12, 2011 (DE) 202011052268.7

(51) Int. Cl. H01L 31/18; H01L 31/02; B32B 38/10; H01L 31/048; B32B 37/18; B32B 37/12

(52) U.S. Cl. CPC H01L 31/18; B32B 37/18; B32B 37/12; B32B 38/10; H01L 31/1892; H01L 31/048; H01L 31/02008; B32B 2457/12
USPC 156/247; 156/349; 136/256

(57) ABSTRACT

The invention relates to a method for manufacturing a semi-finished product for a module having a cell made from a photoactive material, particularly a solar cell, wherein the method has the following steps: providing a substrate (1), arranging a cell (2; 3) made from a photoactive material on the substrate (1) in such a manner that a light-incidence or light-emission side of the cell (2; 3) faces the substrate (1), constructing an adhesive-compound layer (10), into which the cell (2; 3) and a contact connector (7) formed on a connecting lead of the cell (2; 3) are partially or completely embedded, and constructing a contact region (8), which is formed on the rear side of the substrate (1) with the contact connector (7) formed herein, wherein the contact connector (7) is subsequently exposed again to construct the contact region (8), in that a layer composite arranged on the contact connector (7) is removed, and wherein an adhesion between the contact connector (7) and the adhesive-compound layer (10) arranged above the contact connector (7) is diminished to remove the layer composite, in that a cover layer is arranged on the contact connector (7) before the application of the adhesive-compound layer (10) and/or the contact connector (7) and/or at least one region of the adhesive-compound layer (10) arranged next to the contact connector (7) are loaded with an activation energy, and also a device for processing a semi-finished product.

The invention relates to a method for manufacturing a semi-finished product for a module having a cell made from a photoactive material. In an exemplary embodiment, the invention relates to a semi-finished product for a solar module having one or a plurality of solar cells. Furthermore provided are a semi-finished product and a device for the manufacture thereof.

### BACKGROUND

Semi-finished products of this type are used for manufacturing modules having one or a plurality of cells made from a photoactive material. The cells are for example solar cells, that is to say cells having a photoactive material, which absorbs sunlight and converts the same into electrical energy. On the other hand, cells can be used, in which applied electrical energy is converted into light emission. Such photoactive materials are used for example in the form of organic layer stacks, using which so-called organic light-emitting diodes are formed.

Independently of the actual manifestation of the cells in the module, the cells usually have electrical connecting leads, using which in particular an electrical contact between contact connectors on the one hand, by means of which the respective cell is connected to an external wiring, and the photoactive material of the cell on the other hand is produced.

The contact connectors formed on the connecting leads require particular consideration during module manufacture. There is a problem in particular here, in that the contact connectors in the context of the application of the various layers of the module are in the mean time covered by one or a plurality of layers, so that they are subsequently to be exposed again before a use of the contact connectors for electrical contacting can take place. A method for exposing an electrical contact is known from the document DE 10 2009 026 064 A1. The exposure takes place in the suggested method in that a plastic layer covering the contact connector is cut open by means of laser light after the position of the electrical contact connector had previously been determined by means of a sensor.

EP 2 113 945 A1 discloses a method for producing a contacting of solar cells. In the known method, exposure of the contact connector takes place after laminating on a cover layer, in that at least one of the layers covering the solar cells in the desired region is penetrated completely, particularly by means of the stripping of the laminated layer. The hereby-penetrated layer consists of a laminating film for example.

A solar-cell module is known from the document EP 0 867 947 A2.

A method for contacting a photovoltaic module with a connection housing and also a system consisting of a photovoltaic module and a connection housing are described in the document WO 2011/133992 A2.

### SUMMARY

It is the object of the invention to specify improved technologies in connection with a semi-finished product for a module having a cell made from a photoactive material, in which the exposure of an electrical contact connector in a simple and efficient manner is enabled, particularly also subsequently. Generally, a technology should be provided, which facilitates the exposure of one or a plurality of electrical contact connectors in the context of the module manufacture of modules having one or a plurality of cells made from a photoactive material.

This object is achieved according to the invention by means of a method for manufacturing a semi-finished product having a cell made from a photoactive material according to the independent claim 1. Furthermore provided are a semi-finished product according to claim 8 and also a device for processing a semi-finished product according to claim 13. Advantageous configurations of the invention are the subject-matter of dependent subclaims.

In the method for manufacturing a semi-finished product for a module having a cell made from a photoactive material, in which the same is a solar cell for example, a substrate is initially provided. This may be a glass substrate for example. One or a plurality of photoactive cells are arranged on the substrate in such a manner that a light-incidence or a light-emission side of the cell faces the substrate. An adhesive-compound layer is formed. Here, the cell and a contact connector formed on a connecting lead of the cell are partially or completely embedded into the material of the adhesive-compound layer. For example, the adhesive-compound material is painted on, coated on using a doctor blade or sprayed on. When manufacturing the semi-finished product, a rear-side cover layer is manufactured, which is adhesively connected to the adhesive-compound layer at least, whether it be directly or via one or a plurality of layers lying therebetween.

In order to manufacture a semi-finished product for a further assembly process, a contact region with the contact connector arranged herein is then formed on the rear side with respect to the substrate. Contacting of the cell on connecting leads is later enabled via the contact region, for example by means of soldering. To construct the contact region, the contact connector is subsequently exposed again, in that a detachable layer composite or structure arranged on the contact connector, which can also be just single-layered, is removed. The detachable layer composite at least comprises material of the adhesive-compound layer, which was previously arranged above the contact connector in the contact region to be constructed. Here, it is possible for provision to be made to construct predetermined breaking or predetermined tearing points on the layer structure to be detached.

To remove the layer composite, the adhesion between the contact connector and the adhesive-compound layer arranged above the contact connector is diminished. Here, on the one hand, it can be provided to cover the contact connector with a cover element at least to some extent before the application of the adhesive-compound layer, for example to construct a cover layer. Additionally or alternatively, the adhesion diminution is produced, in that the contact connector and/or at least one region of the adhesive-compound layer arranged adjacently to the contact connector are loaded with an activation energy. Here, energy input takes place from outside, preferably with the aid of a contactless energy input method. For example, it can be provided to irradiate laser light.

Alternatively or additionally, an inductive method can be used, in order to input the activation energy, particularly into the metallic contact connector. Therefore, it can be provided that an induction loop arranged outside interacts with the contact connector, in order to input the activation energy. For example, the activation energy input can lead to the contact connector and/or regions of the adhesive-compound layer adjacent thereto heating, as a result of which the adhesion is diminished. However, a mechanical contact diminution with the aid of the activation energy to be input from the outside can also be provided.

When configuring the method, in which the cover element is used on the contact connector, in order to diminish the adhesion between contact connector and adhesive-compound layer, the cover layer can be applied on the contact connector with the aid of various methods, which for example include the adhesive bonding of a cover layer or the spraying on of such a layer. When removing the layer composite above the contact connector, the cover layer is preferably removed together with the adhesive-compound layer.

It can be provided that a rear-side cover layer is formed, which is adhesively connected at least to the adhesive-compound layer.

A preferred development provides that a separating section assigned to the contact region to be constructed is produced for constructing the contact region in the rear-side cover layer, along which the rear-side cover layer is opened during the removal of the layer composite. The separating section can be constructed as an opening and/or predetermined-separating or predetermined-breaking point can be constructed in the form of a material weakness or thinning. For example, a laser separation or weakening can be used in order to prepare the rear-side cover layer in such a manner that, when removing the detachable layer composite or before the rear-side cover layer is opened, so that the layer composite can be removed as a result of this.

In an expedient configuration, it can be provided that the rear-side cover layer is applied using a cover layer opening, which is assigned to the contact region to be constructed and was produced previously. The layer composite can then be removed through the cover layer opening, for the subsequent exposure of the contact connector. The cover layer opening can be realised as a stamped hole for example. The contact region to be constructed can overlap the associated cover layer opening at least to some extent.

An advantageous embodiment provides that when removing the layer composite, a surface layer on the contact connector is removed at least to some extent. For example, an oxide layer on the contact connector can be removed in this manner.

Preferably, a development provides that owing to the loading of the activation energy, a surface region of the contact connector and/or a region of the adhesive-compound layer (10) adjacent to the contact connector soften, or alternatively go so far as to melt. The softening or melting of material on the contact connector, particularly on the surface side, can facilitate the detachment of an oxide layer formed thereon. The softening or melting is a consequence of the input of the activation energy, which in this realisation leads to the heating in the region of the contact connector and/or adjacent regions of the adhesive-compound layer.

In an advantageous configuration, it can be provided that a pull-off element is arranged externally on the layer composite, using which the layer composite can be removed for the subsequent exposure of the contact connector. The pull-off element, which is formed for example using a pull-off layer, can facilitate access to the layer composite to be detached when constructing the contact region. After the gripping of the pull-off element, this can be removed by hand or mechanically together with the layer composite.

Further realisations of the semi-finished product are explained in the following. It can be provided that a cover layer covers the contact connector at least to some extent. A development provides that the rear-side cover layer has a cover layer opening assigned to the contact region to be constructed. In one configuration, it can be provided that a pull-off element is arranged externally on the layer composite.

An advantageous embodiment provides that the cover layer is adhesively arranged on the contact connector and that the adhesive force between the adhesive-compound layer and the cover layer is larger than the adhesive force between the cover layer and the contact connector.

A development provides that the contact region extends in at least one of the following sections on the rear side of the substrate: laterally to the cell and a cell rear side.

Further realisations are explained in the following.

It is made possible using the suggested semi-finished product to subsequently again expose the contact connector, which is used in particular for electrically connecting an external wiring to the cell, in the course of module assembly, after the contact connector was initially covered during the lamination of the layers of the layer arrangement of the module. To this end, in one configuration, a detachable layer composite is provided, which is arranged in the region of the opening of the rear-side cover layer assigned to the contact connector. Therefore, after the adhesive-compound layer, into which the cell is embedded, and also if desired the rear-side cover layer have been applied, the layer composite can be stripped in the region of the cover layer opening assigned to the contact connector, in particular in that the pull-off layer of the detachable layer composite is pulled, in order in this manner to expose the initially covered contact connector again. Here, the adhesive-compound layer tears in the regions which are located below the edge of the cover layer opening or adjacent thereto. The layer composite with a cover layer, which previously protected the contact connector when applying the adhesive-compound layer, the adhesive-compound layer itself and also the pull-off layer formed thereon is removed. Subsequently, the contact connector is available for electrically connecting an external wiring, wherein the electrical connection takes place for example by means of soldering or an electrically conductive adhesive connection. In particular, in all the use of one or a plurality of solar cells in a solar module, a so-called socket connection region can thus be formed.

The adhesive-compound layer extends from below, within the detachable layer composite formed in the region of the cover layer opening, optionally into the cover layer opening and then fills the same partially or essentially completely. This at least partial filling of the cover layer opening with the material of the adhesive-compound layer takes place in one configuration for example when applying the adhesive-compound layer together with the rear-side cover layer. Under loading with pressure, the rear-side cover layer is applied on the rear side together with the adhesive-compound layer or subsequently, for example during solar module manufacture, as a result of which the material of the adhesive-compound layer also moves into the region of the cover layer opening.

The cover layer opening for its part can be closed on the side of the rear-side cover layer, which faces away from the substrate, in such a manner by means of the pull-off layer in one realisation, that a rear-side escape of the material of the adhesive-compound layer through the cover layer opening is prevented. Rather, the layer composite is created hereby, in which the cover layer covers the contact connector and in which the cover layer and the outer pull-off layer are adhesively connected via the adhesive-compound layer and optionally further intermediate layer(s) in such a manner that this layer composite can then be removed for exposure of the contact connector. This removal can take place manually or by means of a mechanical apparatus, for example by means of a mechanically operated gripper. It can be provided that a pull or gripping tab is formed on the pull-off layer, which facilitates the (subsequent) removal of the detachable layer composite.

A plurality of cells made from a photoactive material, for example a plurality of solar cells which form a solar cell arrangement of a solar module, can also be arranged on the substrate. In this configuration with a plurality of cells, the contact region with the contact connector can then be formed between adjacent cells at least to some extent. If the one or the plurality of cells made from photoactive material are realised as solar cells, these may be solar cells with front- and/or rear-side contacting. Solar cells of these different constructions can also be combined with one another in one module. In the case of cells with rear-side contacting, the contact region can be formed on the cell itself at least to some extent, namely on the rear side thereof facing away from the substrate.

The connecting lead, which has the contact connector at one end in the contact region, can in one configuration be formed as a pathway lying on the substrate for example. One cell can be provided with a plurality of such connecting leads, which in each case have a contact connector at the end, which are arranged in the same or different contact regions.

If the semi-finished product for the module has a plurality of contact regions, then a plurality or all of these contact regions are provided in a configuration with a detachable layer composite of the above-described type in the associated cover layer opening.

The one or the plurality of cover layer openings in the rear-side cover layer can be realised for example as a stamped hole in each case. A separation by means of laser cutting can also be provided.

In one configuration, it can be provided that the cover layer is adhesively arranged on the contact connector and that the adhesive force between the adhesive-compound layer and the cover layer is larger than the adhesive force between the cover layer and the contact connector. This supports a subsequent removal of the detachable layer composite, which is as efficient as possible, for exposing the contact connector. The construction of the corresponding adhesive forces between the adjacent layers can take place by means of the direct contact between the layers or optionally with intermediate connection of one or a plurality of intermediate layers. For example, it can be provided to set up the adhesive forces within the detachable layer composite, whilst using adhesion-reinforcing or adhesion-diminishing layers. It can be provided that the external pull-off layer has an adhesion-reinforcing layer on the side thereof facing the substrate, which layer is then in contact with the material of the adhesive-compound layer. Alternatively or additionally, the cover layer, which covers the contact connector at the base of the detachable layer composite, can be provided on the side facing the contact connector with an adhesion-diminishing layer, which ensures an adhesion of the cover layer on the contact connector and on the other hand diminishes this adhesion or bonded contact however, in order to support the subsequent removal of the detachable layer composite for exposure of the contact connector.

A development provides that a plurality of contact connectors are arranged in the contact region, which are electrically isolated and which are assigned to the cell and/or a further cell made from a photoactive material, and that the detachable layer composite is configured to expose the plurality of contact connectors for an electrical contacting when detached. In this configuration, a plurality of contact connectors are exposed together during the removal of the detachable layer composite, that is to say in one step of the removal of the layer composite in the cover layer opening. In one configuration, it can be provided that the plurality of contact connectors are arranged on opposite sides of the contact region.

In one configuration, it can be provided that the pull-off layer and the adhesive-compound layer and/or the adhesive-compound layer and the cover layer are in direct adhesive contact. In this configuration, no additional adhesion-imparting layers, whether it be for reinforcing or for diminishing the adhesive action, are provided between the layers that are respectively involved. The adhesion therefore relates exclusively to the adhesive or bonding action, which is developed by the cover layer, the pull-off layer and the adhesive-compound layer.

One embodiment provides that the cover layer additionally covers a region in the contact region not enclosed by the contact connector. In one configuration, the adhesive layer hereby adheres directly on substrate regions adjacent to the contact connector. In one configuration, it can be provided that the sections, in which the cover layer overhang the actual region of the contact connector itself, encompass or surround the contact connector entirely or completely, as a result of which an optimum protection of the contact connector against the penetration of layer material during lamination of the module layers is formed. The adhesive force between the substrate and the cover layer is expediently smaller than the adhesive force between the cover layer and the adhesive-compound layer.

Preferably, a development provides that the cover layer is delimited in the planar extent thereof to the region of the cover layer opening in the direction of observation from the rear side to the cover layer. Preferably, it can hereby be provided that a peripheral spacing between the outer edge of the cover layer and the peripheral edge of the cover layer opening is formed in the direction of observation towards the rear-side cover layer, wherein the peripheral spacing can also be interrupted in certain sections.

In one configuration, it can be provided that the pull-off layer overlaps with the cover layer at the edge on a side of the rear-side cover layer facing away from the substrate. As a result, it is prevented in an optimised manner that material, particularly the material of the adhesive-compound layer, escapes out of the cover layer opening when pressing the rear-side cover layer.

A development can provide that the pull-off layer is formed encompassing a plurality of cover layer openings. In this embodiment, the pull-off layer interacts with a plurality of detachable layer composites, so that this plurality of contact regions formed separately from one another and having one or a plurality of contact connectors formed herein in each case are exposed during the pulling off of the pull-off layer, whether it be manually or by means of mechanical operating equipment.

A preferred development provides that the adhesive-compound layer consists of a cured adhesive compound originally applied in a pasty or fluid consistency. A bonding agent based on at least one substance from the following group can for example be used as adhesive compounds: silicone, acrylate, polyolefin, polyurethane and a similar plastisol.

In one configuration, it can be provided that the rear-side cover layer is formed from a film or a plate material. Whether it be in the film manifestation or in a different form, the rear-side cover layer can for example consist of ethylene vinyl acetate (EVA). Glass can for example be used as plate material. As a result, the provision of a double-sided glass module is for example enabled.

One embodiment provides that the cover layer and/or the pull-off layer are formed from a sticking tape. In the case of the cover layer, this is preferably a sticking tape adhesive on one or both sides. The pull-off layer is preferably a sticking tape adhesive on one side, wherein the adhesive layer is constructed on the side facing the substrate.

In one configuration, it can be provided that the contact region extends in at least one of the following sections on the rear side of the substrate: laterally to the cell and a cell rear side. The construction of the contact region on the cell rear side can in particular take place in the case of so-called rear contact cells (back contact cells) on the rear-side surface of the cell.

The semi-finished product for a module with a cell made from photoactive material, particularly a solar cell, described in previous embodiments can be manufactured with the aid of a method, which has the following steps: providing a substrate, arranging a cell made from photoactive material on the substrate in such a manner that a light-incidence or a light-emission side of the cell faces the substrate, constructing an adhesive-compound layer, which is adhesively connected to the substrate and the cell and into which the cell is embedded, constructing a rear-side cover layer, which is adhesively connected to the adhesive-compound layer, and constructing a contact region, which is formed on the rear side of the substrate and in which a contact connector of a connecting lead connected to the cell is arranged, wherein the contact region is formed overlapping with an associated cover layer opening at least to some extent and wherein in the region of the cover layer opening and optionally penetrating the same, a layer composite detachable through the cover layer opening for exposing the contact connector is formed, in the case of which a cover layer covers the contact connector and the cover layer and also a pull-off layer are adhesively connected by means of the adhesive-compound layer. A method for manufacturing a module having a cell made from a photoactive material is created in this manner, which comprises the previously mentioned steps. Additionally, a step can then be provided, optionally also temporally offset to the previously mentioned steps, in which the contact connector is exposed in that the layer composite is detached.

### DESCRIPTION OF PREFERRED EXEMPLARY EMBODIMENTS

Further configurations are explained in more detail in the following on the basis of preferred exemplary embodiments with reference to figures of a drawing. In the figures:

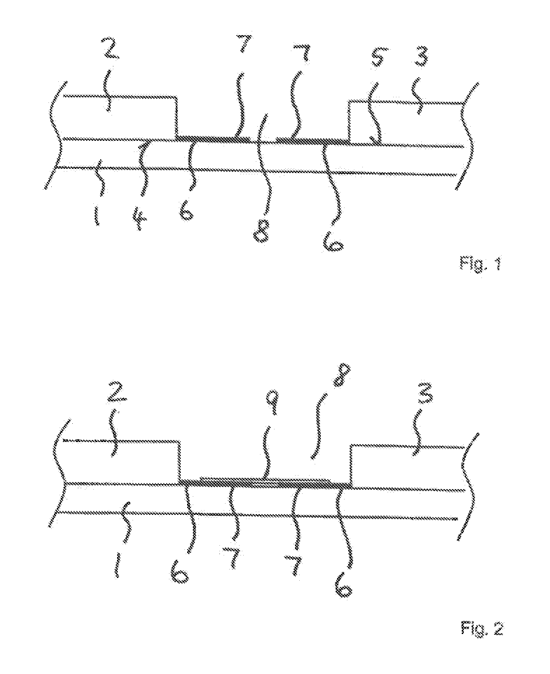

FIG. 1 shows an arrangement for a module having cells made from a photoactive material, in which the plurality of cells are arranged on a substrate, in cross section,

FIG. 2 shows a schematic illustration of the arrangement from FIG. 1, wherein a cover layer is arranged in a contact region, which covers the contact connectors,

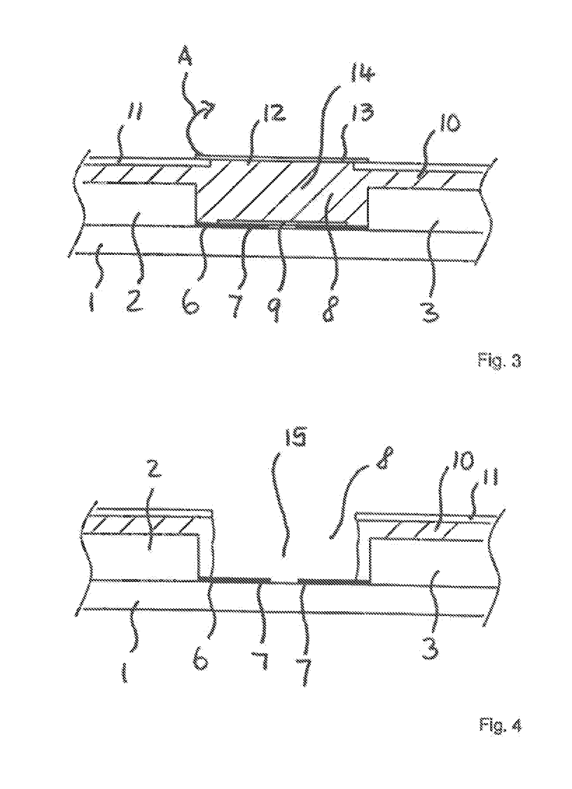

FIG. 3 shows a schematic illustration of the arrangement from FIG. 2, wherein an adhesive-compound layer and also a rear-side cover layer are laminated on,

FIG. 4 shows a schematic illustration of the arrangement from FIG. 3, wherein contact connectors are subsequently exposed,

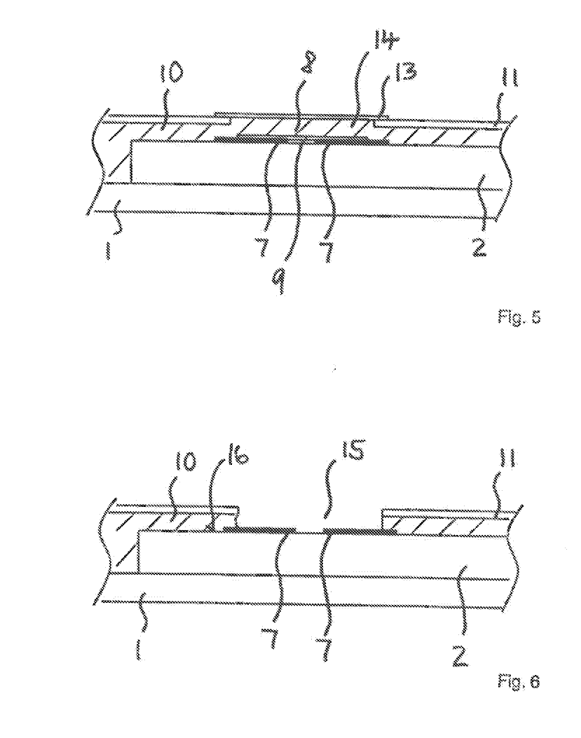

FIG. 5 shows a further arrangement for a module having cells made from a photoactive material, in which the one cell is arranged on a substrate, in cross section, and

FIG. 6 shows a schematic illustration of the arrangement from FIG. 5, wherein contact connectors are subsequently exposed,

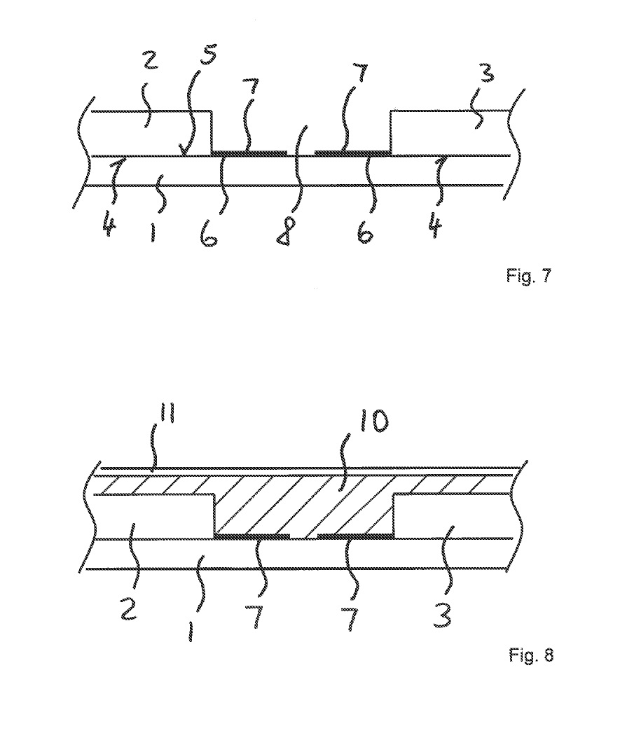

FIG. 7 shows an arrangement for a module having cells made from a photoactive material, comparable to FIG. 1, in which the plurality of cells are arranged on a substrate, in cross section,

FIG. 8 shows a schematic illustration of the arrangement from FIG. 7, wherein an adhesive-compound layer and also a rear-side cover layer are applied,

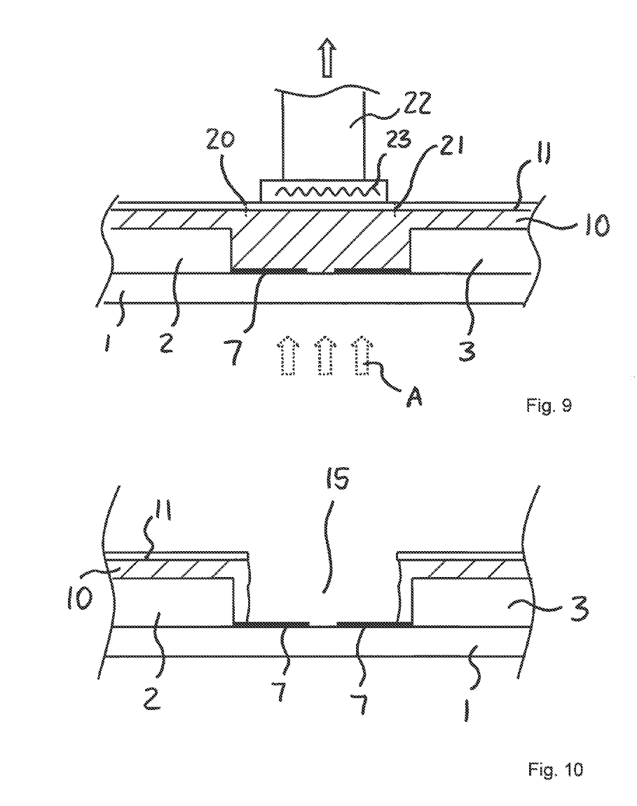

FIG. 9 shows a schematic illustration of the arrangement from FIG. 8, wherein at least the rear-side cover layer is penetrated or weakened and a separating tool is placed for the subsequent exposure of contact connectors, and

FIG. 10 shows a schematic illustration of the arrangement from FIG. 9, wherein the contact connectors are then exposed again.

In the following, reference is made to the schematic illustrations in FIGS. 1 to 4, which show an arrangement for a semi-finished product for a module having cells made from a photoactive material during manufacture. In one configuration, this is an arrangement having solar cells, which can be used for solar module manufacture. In a different configuration, light-emitting cells are provided, using which a light-emitting module can be manufactured, for example having organic light-emitting diodes.

FIG. 1 shows a schematic illustration of a section of an arrangement in cross section, in which cells 2, 3 made from a photoactive material are arranged on the rear side of a substrate 1, which is a glass substrate for example. A front side 4 of the cells 2, 3 is in direct touch contact with a rear side 5 of the substrate 1, without an intermediate layer therefore being formed therebetween. In the case of solar cells, the light-incidence side is located on the front side 4 of the cells 2, 3 facing the substrate.

For electrically contacting the cells 2, 3, that is to say in particular for connecting an external wiring (not illustrated), a connecting lead 6 is formed in each case, which has one contact connector 7 in each case at the end, that is to say at the end distal to the cell 2, 3, which for its part is arranged in a contact region 8, which is formed in the illustrated embodiment between the cells 2, 3. In other configurations (not illustrated), the contact region 8 can also be formed at the edge, that is to say outside of the cell arrangement. Also, a plurality of contact regions with one or a plurality of contact connectors can also be formed internally and/or externally at the edge of a cell arrangement.

FIG. 2 shows a schematic illustration of the arrangement from FIG. 1, wherein the respective contact connectors 7 are now covered with a cover layer 9. Here what is meant for example is a single- or double-sided sticking tape with an adhesive compound, which allows a residue-free removal from the contact connectors 7.

FIG. 3 shows a shows a schematic illustration of the arrangement from FIG. 2, using which a semi-finished product having the cells 2, 3 made from a photoactive material is formed, in which an adhesive-compound layer 10, into which the cells 2, 3 are embedded, and also a rear-side cover layer 11 are applied. The rear-side cover layer 11 has a cover layer opening 12 overlapping with the contact region 8, for example in the form of a stamped hole, into which the material of the adhesive-compound layer 10 extends. The adhesive-compound layer 10 consists for example of a bonding material, which is initially applied in fluid or pasty form, in order to subsequently cure. The laminating on of the rear-side cover layer 11 can take place together with the application of the material for the adhesive-compound layer 10 or subsequently. Various method configurations can be used for this, which are known per se, for example from the document DE 10 2007 038 240 A1.

According to FIG. 3, the cover layer opening 12 is covered with a pull-off layer 13, which in the example shown is arranged externally and at the edge on the rear-side cover layer 11, overlapping the same. A layer composite 14 is formed as a result, in which the cover layer 9 and the external pull-off layer 13 are adhesively connected via the adhesive-compound layer 10 arranged therebetween. This layer composite 14 is arranged above the contact connectors 7 and can then be pulled off for the subsequent exposure of the contact connectors 7, which is indicated in FIG. 3 by means of an arrow A.

FIG. 4 then schematically shows the arrangement from FIG. 3, wherein the contact connectors 7 are now exposed and can be used for electrically contacting the cells 2, 3. The detachable layer composite 14 is removed from the contact connectors 7 again without leaving a residue, an opening 15 is formed in the contact region 8, in which the contact connectors 7 are exposed.

FIGS. 5 and 6 show a further arrangement for a module having cells made from a photoactive material, in which one cell is arranged on a substrate, in cross section. The same reference numbers are used for the same features in FIGS. 5 and 6 as in FIGS. 1 to 4.

FIG. 5 shows a schematic illustration of a section of an arrangement in cross section, in which a cell 2 made from photoactive material is arranged on the rear side on the substrate 1. By contrast with the realisation in FIG. 3, the layer composite 14 and also the contact connectors 7 covered by the same are arranged on a rear side 16 of the cell 2, which is realised in the illustrated realisation as a cell with rear-side contacting (back contact cell).

A further embodiment for an arrangement for a semi-finished product having a module having cells made from photoactive material is explained in the following with reference to FIGS. 7 to 10. In one configuration, this is an arrangement of solar cells, which can be used for solar module manufacture. A further configuration relates to light-emitting cells, using which a light-emitting module can be manufactured, for example having organic light-emitting diodes.

The same reference numbers are used for the same features in FIGS. 7 to 10 as in FIGS. 1 to 6.

FIG. 7 shows a schematic illustration of a section of an arrangement in cross section, in which cells 2, 3 made from a photoactive material are arranged on the rear side of a substrate 1, which is a glass substrate for example. A front side 4 of the cells 2, 3 is in direct touch contact with a rear side 5 of the substrate 1, without an intermediate layer therefore being formed therebetween. In the case of solar cells, the light-incidence side is located on the front side 4 of the cells 2, 3 facing the substrate 1.

For electrically contacting the cells 2, 3, that is to say in particular for connecting an external wiring (not illustrated), a connecting lead 6 is formed in each case, which has one contact connector 7 in each case at the end, that is to say at the end distal to the cell 2, 3, which for its part is arranged in a contact region 8, which is formed in the illustrated embodiment between the cells 2, 3. In other configurations (not illustrated), the contact region 8 can also be formed at the edge, that is to say outside of the cell arrangement. Also, a plurality of contact regions with one or a plurality of contact connectors can also be formed internally and/or externally at the edge of a cell arrangement.

FIG. 8 shows a shows a schematic illustration of the arrangement from FIG. 7, wherein the contact connectors 7 just like the cells 2, 3 made from photoactive material are covered with an adhesive-compound layer 10 in such a manner that the cells 2, 3 are embedded. Furthermore, a rear-side cover layer 11 is applied. By contrast with the realisation in FIGS. 1 to 6, the contact connectors 7 are not covered with the cover layer 9. Rather, the material of the adhesive-compound layer 10 is applied to the contact connectors 7 directly. Thus, the method step for constructing the cover layer 9 is dispensed with. Also, the rear-side cover layer 11 is formed continuously, without it having (cf. FIG. 3 above) the cover layer opening 12 in the configuration shown. In this realisation, a method step for the preceding construction of the cover layer opening 12 is therefore dispensed with.

In a manner comparable to the realisation in FIGS. 5 and 6, the configuration shown in FIG. 8 can also be manufactured on the rear side of one of the cells 2, 3.

In order to subsequently expose the contact connectors 7 again, the rear-side cover layer 11 is initially weakened or optionally penetrated completely according to FIG. 9, in the region of predetermined breaking or predetermined tearing points 20, 21. A laser beam can for example be used to this end, in order to penetrate or to weaken the rear-side cover layer 11 in the desired regions. The extent of a preferably peripherally closed penetration or material weakening is comparable to the extent of the cover layer opening 12 in the above-described configurations. If the rear-side 11 is completely penetrated in certain sections, the thus constructed material separation can extend as far as into the adhesive-compound layer 10 lying therebelow.

Subsequently, an opening 15 is then produced in the contact region 8 according to FIG. 10. To this end, according to FIG. 9, a separating tool 22 is placed on the exterior of the rear-side cover layer 11, using which the layer composite above the contact connectors 7 is pulled off. The adhesion between the separating tool 22 and the rear-side cover layer 11 can be produced in various ways here, for example in that an adhesive compound is applied on the rear-side cover layer 11 and/or the facing surface of the separating tool 22. Alternatively or additionally, an underpressure can be provided in the region of the front surface of the separating tool 22 facing the module, for example in that openings arranged on the surface facing the module are subjected to an underpressure. With the aid of the separating tool 22, the opening 15 shown in FIG. 10 is then created above the contact connectors 7.

Before and/or during the pulling off of the detachable layer composite during the subsequent exposure of the contact connectors 7, the adhesive action between the contact connectors 7 and the adhesive-compound layer 10 is diminished, in order to facilitate the subsequent separation with the aid of the separating tool 22. The adhesion diminution preferably takes place in that energy is introduced into the contact region between the contact connectors 7 and the adhesive-compound layer 10 arranged hereon, for example in the form of light energy, heat energy and/or electromagnetic energies or in a different form. For example, a warming of the contact connectors 7 occurs, which diminishes the adhesion to the material of the adhesive-compound layer 10. If the contact connectors 7 are provided with a solder material, then it may occur that the solder material liquefies at least on the surface at least to some extent, as a result of which external layers are also pulled off when pulling off the material of the adhesive-compound layer 10 arranged hereon. As a result, external oxide layers on the contact connectors 7 are also removed, so that the disruptive action thereof is overcome during later contacting at the contact connectors 7.

According to the schematic illustration in FIG. 9, the energy input can take place in various ways. In one configuration, the separating tool 22 itself has a source 23 of the energy to be input into the region of the contact between the contact connectors 7 and the adhesive-compound layer 10. Alternatively or additionally, the contact region for diminishing the adhesive action between contact connectors 7 and adhesive-compound layer 10 can also be loaded with energy through the substrate 1 (cf. arrow A). For example, the use of laser light can be provided here. In connection with the use of the source 23 on the separating tool 22, an inductive energy input can be provided. However, the use of a heat energy source, for example a heating loop, can also be provided. The energy input can also alternatively or additionally take place through the rear-side cover layer 11, without the energy source being formed in the separating tool 22 itself.

The rear-side cover layer 11 is formed in the described realisation. In the various configurations, it can also be provided to realise the manufacture of the contact region 8 without the rear-side cover layer 11 being formed. In a simple case, only the adhesive-compound layer 10 is removed hereby in the desired region. Here, it can be provided to prepare the same comparably to the predetermined breaking or predetermined tearing points 20, 21 in FIG. 9, for the removal of the adhesive-compound layer 10, for example by means of scoring.

The features of the invention disclosed in the previous description, the claims and the drawing can be of importance both individually and in any desired combination for realising the invention in its various configurations.

1. A method for manufacturing a semi-finished product for a module having a cell made from a photoactive material wherein the method comprises the following steps:
providing a substrate,
arranging a cell made from a photoactive material on the substrate in such a manner that a light-incidence or a light-emission side of the cell faces the substrate,
constructing an adhesive-compound layer, into which the cell and a contact connector formed on a connecting lead of the cell are partially or completely embedded, and
constructing a contact region, which is formed on the rear side of the substrate with the contact connector formed herein,
wherein the contact connector is subsequently exposed again to construct the contact region, in that a layer composite arranged on the contact connector is removed, and
wherein an adhesion between the contact connector and the adhesive-compound layer arranged above the contact connector is diminished to remove the layer composite, in that a cover layer is arranged on the contact connector before the application of the adhesive-compound layer or the contact connector or at least one region of the adhesive-compound layer arranged next to the contact connector are loaded with an activation energy.

2. The method according to claim 1, wherein a rear-side cover layer is formed, which is adhesively connected at least to the adhesive-compound layer.

3. The method according to claim 2, wherein, to construct the contact region in the rear-side cover layer, a separating section assigned to the contact region to be constructed is produced, along which separating section, the rear-side cover layer is opened when removing the layer composite.

4. The method according to claim 2, wherein the rear-side cover layer is applied using a cover layer opening, which is assigned to the contact region to be constructed and is previously produced.

5. The method according to claim 1, wherein a surface layer on the contact connector is at least partially removed when removing the layer composite.

6. The method according to claim 1, wherein, owing to the loading of the activation energy, a surface region of the contact connector or a region of the adhesive-compound layer adjacent to the contact connector soften, or as far as melting.

7. The method according to claim 1, wherein a pull-off element is arranged externally on the layer composite, using which the layer composite can be removed for the subsequent exposure of the contact connector.

8. A semi-finished product for a module having a cell made from a photoactive material, particularly a solar cell, having a layer arrangement, the layer arrangement comprising:
a substrate,
a cell made from a photoactive material on the substrate in such a manner that a light-incidence or light-emission side of the cell faces the substrate, and
an adhesive-compound layer, into which the cell and a contact connector formed on a connecting lead of the cell are partially or completely embedded,
wherein a detachable layer composite for the subsequent exposure of the contact connector is formed for constructing a contact region on the rear side of the substrate having the contact connector arranged herein.

9. The semi-finished product according to claim 8, wherein a cover layer covers the contact connector at least partially.

10. The semi-finished product according to claim 8, wherein a pull-off element is arranged externally on the layer composite.

11. The semi-finished product according to claim 8, wherein the cover layer is arranged adhesively on the contact connector and in that the adhesive force between the adhesive-compound layer and the cover layer is larger than the adhesive force between the cover layer and the contact connector.

12. The semi-finished product according to claim 8, wherein the contact region extends in at least one of the following sections on the rear side of the substrate: laterally to the cell and a cell rear side.

13. A device for processing a semi-finished product for a module having a cell made from a photoactive material, particularly by means of a method according to claims 1, having:
a workpiece mounting for mounting a semi-finished product for a module with a cell made from a photoactive material, and
a separating tool, which is suitable for removing a detachable layer composite for constructing a contact region having a contact connector arranged herein on the rear side of a substrate of the semi-finished product, so that the contact connector in the contact region is subsequently exposed.

14. The device according to claim 13, further comprising an energy-input apparatus, which is configured when processing the semi-finished product to provide an activation energy and, for removing the layer composite, to load the contact connector or at least one region of an adhesive-compound layer arranged adjacently to the contact connector with the activation energy, in order to diminish an adhesion between the contact connector and the adhesive-compound layer arranged above the contact connector.

15. The device according to claim 14, wherein the energy-input apparatus is arranged on the separating tool.
